(19) United States
(12) Patent Application Publication
(10) Pub. No.: US 2008/0256426 A1
(43) Pub. Date: Oct. 16, 2008

(54) Low Density Parity Check Codes For Mimo Systems

(75) Inventors: Anthony Reid, Plano, TX (US); Kyeong Jim Kim, Irving, TX (US); Victor Stolpman, Irving, TX (US)

Correspondence Address: SQUIRE, SANDERS & DEMPSEY L.L.P., 8000 TOWERS CRESCENT DRIVE, 14TH FLOOR, VIENNA, VA, 22182-6212, US

(73) Assignee: Nokia Siemens Networks Oy

(21) Appl. No.: 11/667,675

(22) PCT Filed: Nov. 10, 2005
(86) PCT No.: PCT/FI05/00481

§ 371 Date: Nov. 26, 2007

Related U.S. Application Data
(60) Provisional application No. 60/627,024, filed on Nov. 12, 2004.

(51) Int. Cl. H03M 13/11

(52) U.S. Cl. 714/801

(57) ABSTRACT

A low density parity check code is generated by defining first a framework combining symbol detection and low density parity check decoding. Probabilistic information describing multiple-input-multiple-output channels is defined, and a low density parity check code is generated based on said framework and said probabilistic information describing multiple-input-multiple-output channels.

### FIELD OF THE INVENTION

The present invention relates to generating low density parity check codes and to using the designed low density parity check codes. In particular, the present invention relates to generation of low density parity check codes for multiple-input-multiple-output (MIMO) channels.

### BACKGROUND OF THE INVENTION

A communication system can be seen as a facility that enables communication between two or more entities such as user equipment and/or other nodes associated with the system. The communication may comprise, for example, communication of voice, data, multimedia and so on. The communication system may provide circuit switched and/or packet switched communications. The communication system may be configured to provide wireless communication.

Communication systems employ coding to enhance the reliability of communication over noisy channels. Recently, low density parity check (LDPC) codes have become subject to extensive research. Low density parity check codes are a special type of linear block codes.

In receiving symbols sent over a noisy channel, a first step is typically signal detection. Signal detection means estimating symbols sent over the channel based on the received symbols, which have been affected by the channel properties. A second step is decoding, which uses symbol estimates from the signal detection. The signal detection and decoding may use hard or soft decisions. In traditional signal detection and decoding techniques, the received symbols are first detected and then the received symbols are decoded. These steps are performed separately, without providing any feedback information from the decoding step to the detection step.

In iterative symbol detection and decoding techniques information is passed between the detection and the decoding steps. These iterative techniques have better performance than traditional symbol detection and decoding techniques. The iterative techniques pass soft-likelihoods between the signal detection and decoding steps. Various iterative decoding methods for LPDC codes are known.

LDPC codes are traditionally designed for an Additive Gaussian White Noise (AWGN) channel. Recently there have been some proposals on using other types of channels. In connection with single-input-single-output (SISO) channels, J. Hou, P. Siegel and L. Milstein have proposed taking channel properties into account in LDPC code design in “Performance analysis and Code Optimization of Low Density Parity Check Codes on Rayleigh Fading Channels”, IEEE J. Select. Areas Commun., Issue on The Turbo Principle: From Theory to Practice I, vol. 19, no. 5, pp. 924-934, May 2001.

LDPC codes have been designed for partial response channels by N. Varnica and A. Kavcic, in “Optimized low-density parity-check codes for partial response channels,” IEEE Communications Letters, Vol. 7, issue 4, April 2003, pp. 168-170. LDPC codes have also been designed using exit charts and mutual information that is a function of the channel by S. ten Brink, G. Kramer, and A. Ashikhmin, in “Design of Low-Density Parity-Check Codes for Multi-Antenna Modulation and Detection,” submitted to IEEE Trans. Commun., June 2002. The exit charts are discussed by A. Ashikhmin, G. Kramer and S. ten-Brink, in “Code rate and the area under extrinsic information transfer curves”, Proceedings. IEEE International Symposium on Information Theory, 2002, p. 115.

It is, however, appreciated that LDPC codes used with multiple-input-multiple-output (MIMO) channels are generally designed for AWGN channels. The multiple channels existing between the receive and transmit antennas cause the design process of LDPC codes to be complex for MIMO channels. In detecting and decoding signals sent over MIMO channels, the channel properties are typically taken into account in signal detection. Coder/decoder pairs are designed and defined off-line through analysis and/or simulation of expected channel conditions.

The present invention aims to provide adaptivity to the use of the codes by taking into account information on MIMO channel properties in designing low density parity check codes and in using low density parity check codes in MIMO systems.

### SUMMARY OF THE INVENTION

In accordance with a first aspect of the present invention, there is provided a method for generating a low density parity check code, the method comprising defining a framework combining symbol detection and low density parity check decoding,
determining probabilistic information describing multiple-input-multiple-output channels, and
generating a low density parity check code based on said framework and said probabilistic information describing multiple-input-multiple-output channels.

In accordance with a second aspect of the present invention, there is provided a method for low density parity check decoding, the method comprising receiving information transmitted over multiple-input-multiple-output channels,
determining information describing said multiple-input-multiple-output channels, and
determining a low density parity check codeword relating to said received information and to a low density parity check code using at least said received information, said information describing said multiple-input-multiple-output channels, and a framework combining symbol detection and low density parity check decoding.

In accordance with a third aspect of the present invention, there is provided a decoder for low density parity check codes, configured to receive information transmitted over multiple-input-multiple-output channels,
determine information describing said multiple-input-multiple-output channels, and
determine a low density parity check codeword relating to said received information and to a low density parity check code using at least said received information, said information describing said multiple-input-multiple-output channels, and a framework combining symbol detection and low density parity check decoding.

In accordance with a fourth aspect of the present invention, there is provided a decoder for low density parity check codes, comprising
means for receiving information transmitted over multiple-input-multiple-output channels,
means for determining information describing said multiple-input-multiple-output channels, and
means for determining a low density parity check codeword relating to said received information and to a low density parity check code using at least said received information, said information describing said multiple-input-multiple-output channels, and a framework combining symbol detection and low density parity check decoding.

### BRIEF DESCRIPTION OF THE DRAWINGS

Embodiments of the present invention will now be described by way of example only with reference to the accompanying drawings, in which:

FIG. 1 shows a receiver in accordance with the prior art,

FIG. 2 shows, as example, a bipartite graph relating to a low density parity check code,

FIG. 3 shows, as an example, a factor graph relating to a first embodiment of the invention for a 4×4 MIMO system,

FIG. 4 shows, as an example, recursive decoding for low density parity check codewords,

FIG. 5 shows, as an example, a factor graph relating to a second embodiment of the invention for a 4×4 MIMO system,

FIG. 6 shows a receiver in accordance with an embodiment of the invention, and

FIG. 7 shows, as an example, a typical lay-out for a possible packet format in a MIMO system.

### DETAILED DESCRIPTION OF EMBODIMENTS OF THE INVENTION

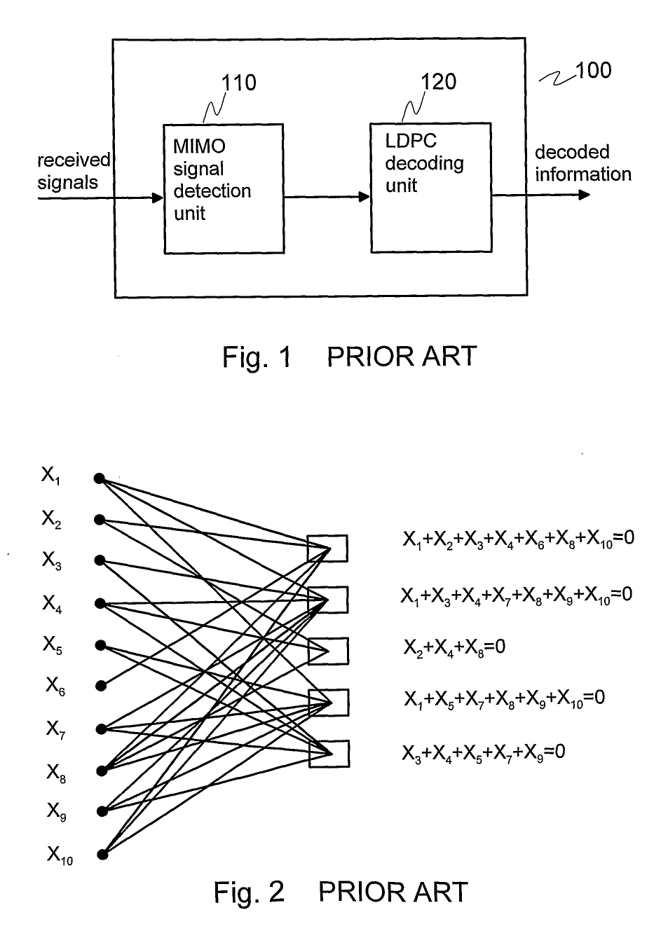

Embodiments of the present invention combine signal detection and decoding in a multiple-input-multiple-output system into a unified framework. To explain this in more detail, reference is first made to a conventional receiver. FIG. 1 shows a receiver 100 in accordance with the prior art. The receiver 100 has a MIMO signal detection unit 110 and a LDPC decoding unit 120. It is appreciated that the receiver 100 may further have an interleaving unit between the signal detection unit 110 and the LDPC coding unit 120.

Information about the MIMO channel properties is taken into account in the signal detection unit 110, typically by determining a channel matrix H. A received symbol (or a set of received symbols) y relates to the estimated sent symbol x by y=Hx+n, where n represents noise. The estimated sent symbol x are called the detected symbol. As explained in connection with the background of the invention, the LDPC decoding unit 120 takes the symbol estimates x from the signal detection unit 110 as input. The LDPC codes employed in the LDPC decoding unit 120 have typically been designed using information about an AWGN channel.

A LDPC code may be represented with a bipartite graph. FIG. 2 shows an example of a bipartite graph having n message nodes, r check nodes and edges connecting messages nodes and check nodes. Each message node represents a bit of a codeword. The valid codewords are those vectors c (c₁, . . . , cₙ) such that for all the check nodes the sum of the neighboring positions among the messages nodes is zero. The LDPC code is defined by a r×n parity check matrix, denoted here with P, or by a generator matrix, denoted here with G. For valid codewords c, Pc^{T}=0. Edges of a bipartite graph shown in FIG. 2 correspond to the entries in the parity check matrix P. It is known how to determine a generator matrix G from a given parity check matrix P and vice versa.

For the receiver 100, the estimated symbols x output from the signal detection unit 110 are directly linked to the codewords. The LDPC decoding unit 120 thus receives no information about the MIMO channel properties. LDPC decoding is carried out in the receiver 100 using a known parity check matrix P and the estimated symbols x. It is possible that the estimated symbols x do not form a valid codeword, due to, for example, transmission errors or inaccuracies in detecting the symbols. In the LDPC decoding the aim is to compensate errors in transmission and inaccuracies in symbol detection and to figure out, which set of symbols (valid codeword) was actually sent.

Embodiments of the present invention combine signal detection and decoding in a multiple-input-multiple-output system into a unified framework. In the following, some embodiments of the invention are discussed with reference to factor graphs. The use of factor graphs allows edge-transition probabilities between the MIMO receiver codeword nodes and the LDPC parity check nodes to be defined in a common probabilistic framework.

In the following description, a MIMO OFDM (Orthogonal Frequency Division Multiplexing) system is used as an example. Statistical characterization of MIMO OFDM channels is feasible due to each OFDM carrier being a flat-fading channel. It is, however, appreciated that other multiplexing methods in MIMO systems may be treated similarly.

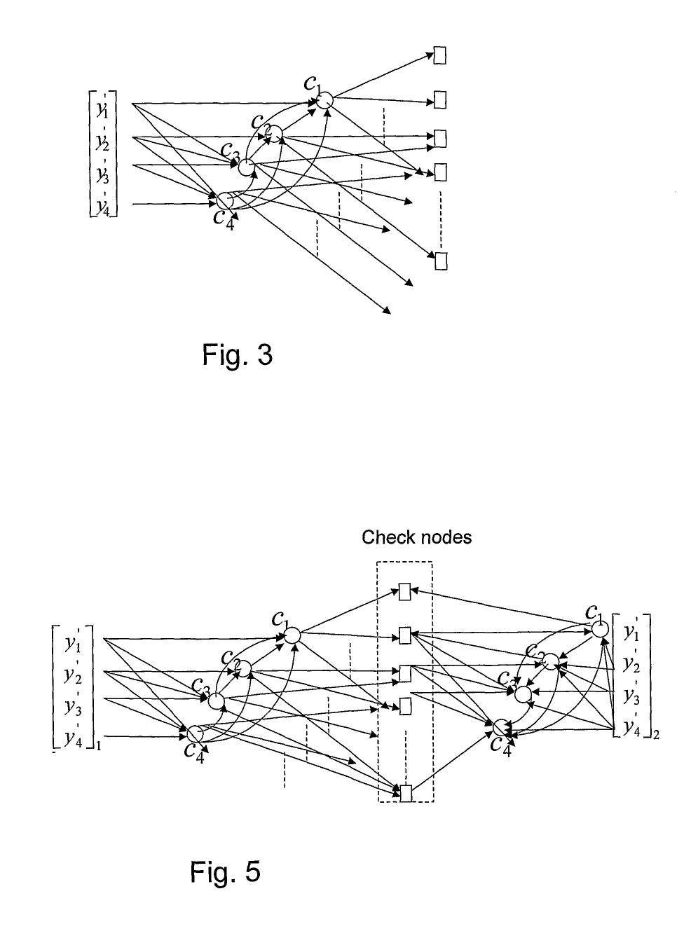

FIG. 3 shows a factor graph relating to a first embodiment of the invention. In this embodiment, a MIMO channel matrix H is decomposed into a set of matrices which allows successive interference cancellation. In the MIMO OFDM, the decomposition is applied to each OFDM frequency bin. As an example, such a set of matrices is the QR decomposition, where R is an upper-triangular matrix and Q^{H}Q=I. The relation between an estimated sent symbol x (detected symbol) and a received symbol y is thus y=Hx+n, where H=QR. This equation can be modified into y′=Q^{H}y=Rx+Q^{H}n=Rx+n′.

In a conventional MIMO system, where the symbol detection and decoding are carried out separately, the components of the estimated vector x are directly linked to the codeword nodes of a bipartite graph defining a LDPC code. In this unified framework, the entries of the matrix R define how the modified received symbols y′ are linked to codeword nodes. Furthermore, the codeword nodes are linked to each other through transition probabilities depending on the entries in the matrix R. The edges between the codeword nodes and the check nodes are defined by the bipartite graph of the LDPC code. FIG. 3 shows, as an example, a factor graph relating to the equation y′=Rx+n′ for a 4×4 MIMO system, where there are four transmit antennas and four receive antennas. The matrix equation y′=Q^{H}y=Rx+n′ for the 4×4 system is

$${y}^{′} = {Q}^{H} y = [ \begin{matrix}{y}_{1}^{′} \\ {y}_{2}^{′} \\ {y}_{3}^{′} \\ {y}_{4}^{′}\end{matrix} ] = [ \begin{matrix}{r}_{1 , 1} & {r}_{1 , 2} & {r}_{1 , 3} & {r}_{1 , 4} \\ 0 & {r}_{2 , 2} & {r}_{2 , 3} & {r}_{2 , 4} \\ 0 & 0 & {r}_{3 , 3} & {r}_{3 , 4} \\ 0 & 0 & 0 & {r}_{4 , 4}\end{matrix} ] [ \begin{matrix}{c}_{1} \\ {c}_{2} \\ {c}_{3} \\ {c}_{4}\end{matrix} ] + {n}^{′} .$$

In FIG. 3, the vector y′ represents a subset of LDPC measured codeword nodes. The LDPC check nodes are all present in the factor graph in FIG. 3.

FIG. 3 thus shows an example of a factor graph linking modified received symbols y′ to LDPC code check nodes. Generation of LDPC codes, in other words generation of a parity check matrix P or generation of a generator matrix G, based on the factor graph linking modified received symbols y′ to check nodes is evident to a person skilled in the art of LDPC coding. There are at least two possibilities for designing the LDPC code by incorporating information about MIMO channel properties.

A first option for designing the LDPC code is to employ density evolution. In this case, a probabilistic description of a MIMO channel is needed. This probabilistic information may be in a simple closed form for making the design process less cumbersome. When the QR decomposition, or a similar decomposition enabling successive interference cancellation, is used, the channel matrix elements are converted into variants of chi-squared probability density functions. This density evolution approach can be similar to the approach described by J. Hou, P. Siegel and L. Milstein.

It is appreciated that for designing a LDPC code using the factor graphs, it is necessary to determine the probability density functions for each element of the matrix R and for the other transitions in the factor graph linking modified received symbols to LDPC check nodes. For determining the probability density functions of the matrix elements of R, one possible approach is to perform channel categorization work for defining a reasonable class of channels. This approach may lead to simplified probability density functions for the MIMO channels based on some statistical techniques. Density evolution is another option for determining probability density functions for the matrix elements of R. For flat fading ITU models, the probability density functions of each element of matrix R are some variants of χₙ², χₘ and they are also statistically independent. The probabilities for codeword-to-codeword transitions have been determined.

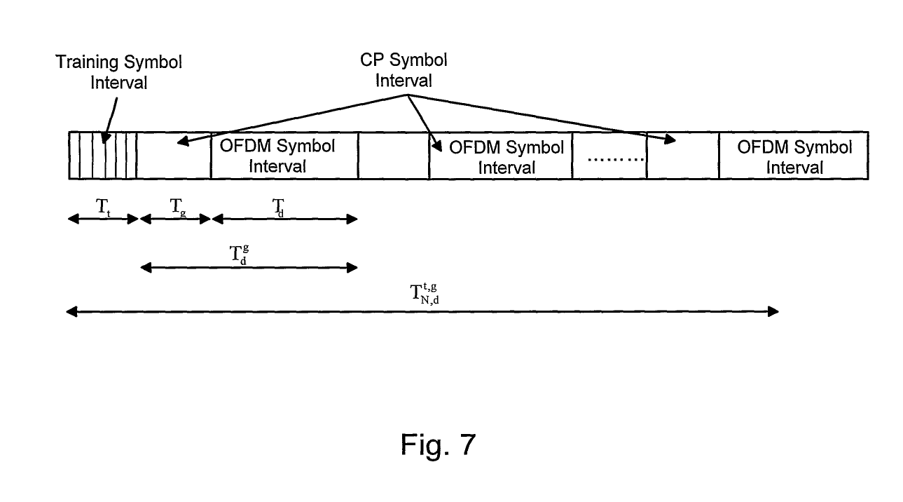

A detailed example of the calculations of the probabilities along the edge transitions of the input nodes is described later with reference to FIG. 7.

Another option for designing the LDPC code using the factor graph framework is to employ EXIT charts. The use of EXIT charts requires ensemble averaging over many channel realizations to design the parity check matrix.

In any of these options, the design of the LDPC code may be carried out off-line based on the analytic or approximated form of the channel probability density functions or by enumerating channels realizations for a channel probability density function.

The designed LDPC code is used in encoding information similarly as any other LDPC code. In the receiving end, the designed LDPC code is used in a step combining signal detection and LDPC decoding. Information about the channel properties of the current channel instance is used in this step combining signal detection and LDPC decoding. Recursive likelihood equations reflect the statistical relationships between the MIMO receiver and the LDPC code component.

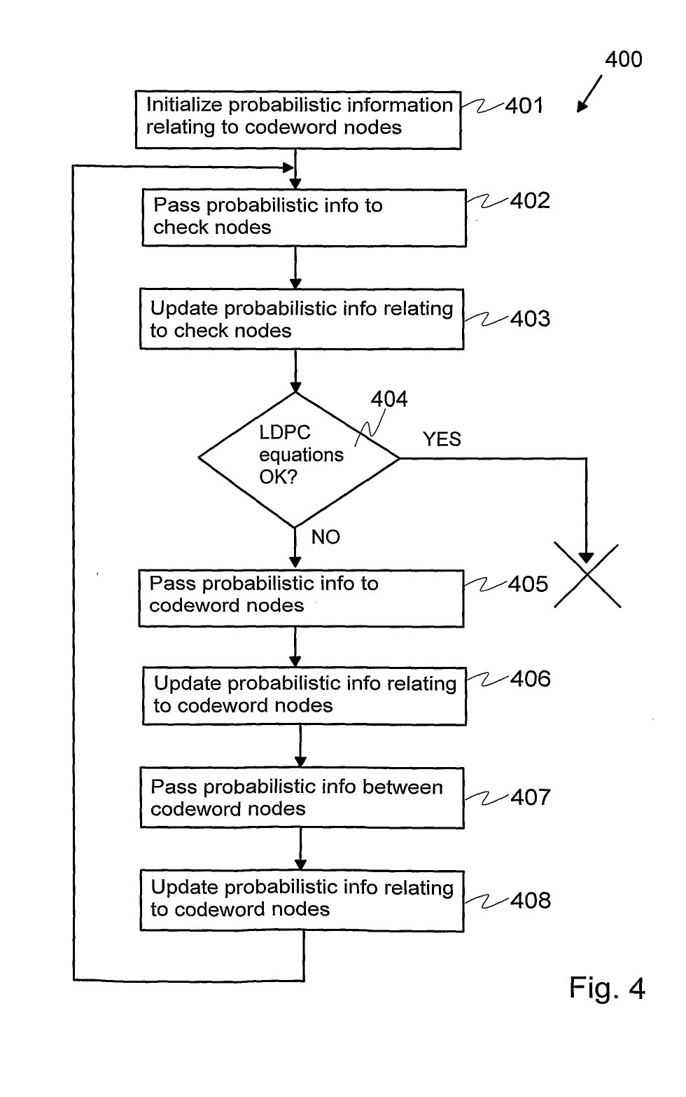

The generation of a LDPC code and decoding of a LDPC codeword are typically recursive processes. An example of this recursion for decoding is shown in FIG. 4. In step 401, the probabilistic information relating to the codeword nodes is initialized. In step 402, probabilistic information is passed to the check nodes. In step 403, probabilistic information relating to the check nodes is updated. In step 404, it is check whether the LDPC parity check equations are valid. If the LDPC parity check equations are not valid, probabilistic information is passed to codeword nodes in step 405. In step 406, probabilistic information relating to the codeword nodes is updated. Thereafter, probabilistic information is passed between the codeword nodes in step 407. In step 408, probabilistic information relating to the codeword nodes is updated again. The method continues thereafter from step 402.

FIG. 5 shows a factor graph relating to a further embodiment of the invention. In this second embodiment, two decompositions of the channel matrix H are used: E=Q₁R₁ and H=Q₂R₂, where R₂ is a lower-triangular matrix. The second decomposition of the channel matrix is used to provide a second set of channel observables. These could have been used for successive interference cancellation in the traditional QRD-M algorithm to provide an LDPC with codeword inputs. In the factor graph shown in FIG. 5, the recursion is defined to increase the girth (that is, the length) of the cycles in the factor graph. It has been observed that performance of the LDPC codes is improved by increasing the cycle length. This symmetric factor graph may also affect in establishing symmetry properties for the probability density functions involved in generating LDPC codes using density evolution.

Let C₁ and C₂ be defined as sets of codeword nodes for the upper-triangular matrix R₁ and for the lower-triangular matrix R₂, respectively. Let P be defined as the set of parity check nodes. The factor graph in FIG. 5 relates to the following equations: y₁′=Q₁^{H}y=R₁x+n₁ and y₂′=Q₂^{H}y=R₂x+n₂: Similarly as in the first embodiment, the transition probabilities of the matrix elements of the upper-triangular matrix R₁ and of the lower-triangular matrix R₂ and the codeword to codeword transition probabilities are needed for generating LDPC codes and for decoding in this embodiment.

A fall-cycle recursion for both generating a LDPC code and for decoding a LDPC codeword may be, for example, the following. Probabilistic information is passed from nodes C₁ to the parity check nodes P for updating probabilities of the parity check nodes. Probabilistic information is then passed from the parity check nodes P to the codeword nodes C₂ for updating probabilistic information relating to these codeword nodes C₂. Thereafter, probabilistic information is passed between the codeword nodes C₂. Updated probabilistic information is then passed from the codeword nodes C₂ to the parity check nodes P for updating probability information relating to the parity check nodes. From the parity check nodes P probabilistic information is passed to codeword nodes C₁, and thereafter between the codeword nodes C₁.

It is appreciated that different LDPC codes may be defined for different channel conditions. One example of different channel conditions is hilly vs. flat terrains. The different channel conditions are taken into account in the LDPC code design with different channel properties. In using the LDPC codes for encoding and decoding, there may be simple metric in use for determining which LDPC code of the available LDPC codes to use.

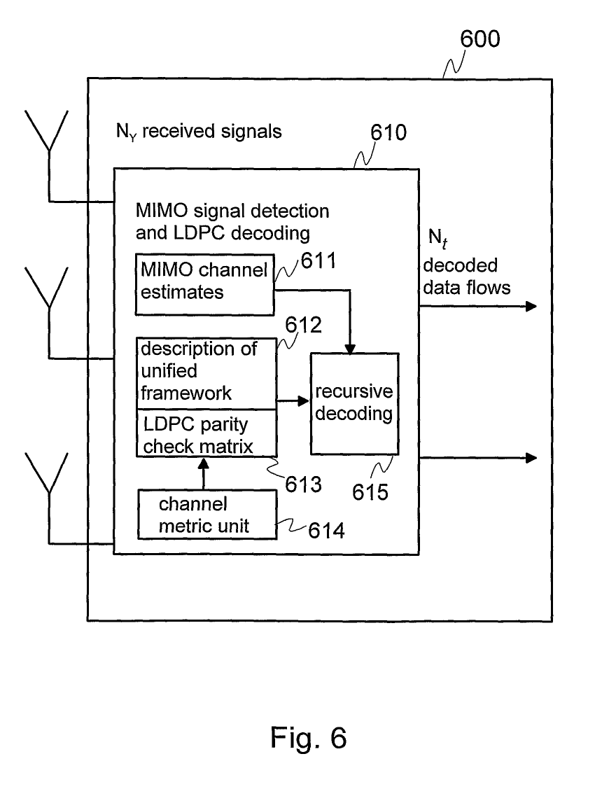

FIG. 6 shows, as an example, a receiver 600 in accordance with an embodiment of the invention. The receiver 600 contains a combined MIMO signal detection and LDPC decoding unit 610. This combined signal detection and LDPC decoding unit 610 contains a MIMO channel estimator 611 and a storage 612 for storing information describing a unified framework. As part of the information describing the unified framework, there is information defining the LDPC code 613. This information is typically the LDPC parity check matrix P. If the receiver 600 is able to select from a plurality of different LDPC codes, the receiver 600 typically contains a channel metric unit 614, which selects the desired LDPC code. A MIMO transmitter sending the information has a corresponding channel metric unit, and the encoding has been carried out using the selected LDPC code. Information about the unified framework, including the desired LDPC code, is input to a recursive decoding unit 615. Also information about the channel properties is input to the recursive decoding unit 615. The decoding results in a plurality of data flows corresponding to the number of the MIMO transmitters.

The required data processing functions may be provided by means of one or more data processor entities. Required processing functions may be provided in the receiver of FIG. 6. Appropriately adapted computer program code product may be used for implementing the embodiments, when loaded to a computer, for example for the above computations. The program code product for providing the operation may be stored on and provided by means of a carrier medium such as a carrier disc, card or tape. A possibility is to download the program code product via a data network. Implementation may be provided with appropriate software in a server.

A possibility for the graph is the so called Tanner graph which has edges, nodes and probabilities for edge transitions. The following is a detailed example of calculations based on a Tanner description of the input/output, and is given with reference to FIG. 7. It shall be appreciated that the calculation of probabilities between codeword nodes and parity check nodes in a Tanner graph can be computed similarly than in a generic LDPC code, and therefore the following example is given only to assist in understanding the invention, with no intention to limit the invention to this example.

In the following example, we consider a baseband model for a received MIMO OFDM signal over multipath fading channel. The MIMO OFDM system is equipped with multiple antennas at the transmitter and the receiver. Throughout this example, scalar variables are written as plain lower-case letters, vectors as bold face lower-case letters and matrices as bold-face upper-case letters. Some further notations to describe signal and channel models for the MIMO OFDM system include the following:
N_{f}: the number of multipaths.
Nₜ, Nᵣ: numbers of antennas in the transmitter and the receiver, with Nₜ=Nᵣ.
N−1: the number of OFDM data symbols in one packet.
K: the number of subcarriers.
T_{g}: the guard time interval.
Tₛ: the sampling time.
T_{d}: the OFDM data symbol interval, defined by T_{d}ΔKTₛ.
Tₜ: the OFDM training symbol interval, Tₜ=MₜTₛ.
T_{N,d}^{t,g}: the packet interval, T_{N,d}^{t,g}ΔTₜ+(N−1)×(T_{g}+T_{d})ΔTₜ+(N−1)×T_{d}^{g}.
A, a, (A)_{l,m}, (a)ₖ: a matrix, a vector, the (l, m) element of the matrix A, and the k-th element of the vector a.
p, q, k, m⁺, m: indices for the transmit antenna, the receiver antenna, the subcarrier, the OFDM data symbol, the OFDM symbol with 1≦p≦Nₜ, 1≦q≦Nᵣ, 1≦k≦K, 1≦m⁺≦N−1, 0≦m≦N−1,

As shown in FIG. 7, one OFDM packet is composed of (N−1) OFDM data symbols with one OFDM training symbol which is made up of Mₜ subcarriers. Guard time interval is also included in each data symbol to eliminate ISI. At a packet time n, a set of independent input symbols {\tilde{d}ₖ^{p}(nN)}/{dₖ^{p}(nN+m⁺)}, determined by the outputs of the convolutional encoder is input to the p-th modulator (a Mₜ/K-point IFFT) which modulates input symbols onto Mₜ/K subcarriers. Input symbols are chosen from a complex-valued finite alphabet. Here, {\tilde{d}ₖ^{p}(nN)} is a set of training symbols for the n-th packet. For our convenience, we assume the same signal constellation for all subcarriers and antennas.

The outputs of the p-th modulator in the interval, nT_{N,d}^{t,g}≦t≦(n+1)T_{N,d}^{t,g}, is

$$\begin{matrix}{s}^{p} ( t ) = {s}_{{D}_{0}}^{p} ( t ) pT ( t - {nT}_{N , d}^{t , g} ) + {\sum }_{{m}^{+} = 1}^{N - 1} {s}_{{D}_{{m}^{+} }}^{p} ( t ) {p}_{D} ( t - {T}_{t} - {T}_{g} - {T}_{d}^{g} ( {m}^{+} - 1 ) - {nT}_{N , d}^{t , g} ) ; \\ {s}_{{D}_{0}}^{p} ( t ) = \frac{1}{\sqrt{{M}_{t}}} {\sum }_{k = 0}^{{M}_{t} - 1} {\tilde{d}}_{k}^{p} ( nN ) {ⅇ}^{j2π k ( t - {nT}_{N , d}^{t , g} ) / {T}_{t}} , & ( 1 ) \\ {s}_{{D}_{m}^{+}}^{p} ( t ) = \frac{1}{\sqrt{K}} {\sum }_{k = 0}^{K - 1} {d}_{k}^{p} ( nN + {m}^{+} ) {ⅇ}^{j2π k ( t - {T}_{t} - {T}_{g} - {T}_{d}^{g} ( {m}^{+} - 1 ) - {nT}_{N , d}^{t , g} ) / {T}_{d}} . & \end{matrix}$$

In (1), p_{T}(t) and p_{D}(t) are respectively pulse shapes supporting only on [0,Tₜ) and [0,T_{d}). For simplicity of notation, the explicit dependence on the packet index nN will be suppressed in the sequel. The channel between the p-th transmit antenna and the q-th receive antenna, {fₗ^{p,q}(m)}, is modeled by a tapped delay line (TDL) with taps, fₗ^{p,q}(m)εC, spaced Tₛ sec apart [[7],Chap-7], such that the received signal at the q-th antenna is

$${r}^{q} ( t ) = {r}_{0}^{q} ( t ) + {\sum }_{{m}^{+} = 1}^{N - 1} {r}_{{m}^{+}}^{q} ( t ) + {n}^{q} ( t ) , \\ {r}_{0}^{q} ( t ) {=}^{Δ} {\sum }_{p = 1}^{{N}_{t}} {\sum }_{l = 0}^{{N}_{f} - 1} {f}_{l}^{p , q} ( 0 ) {s}_{{D}_{0}}^{p} ( t - {lT}_{s} - {T}^{p , q} ( 0 ) ) , \\ {r}_{{m}^{+}}^{q} ( t ) {=}^{Δ} {\sum }_{p = 1}^{{N}_{t}} {\sum }_{l = 0}^{{N}_{f} - 1} {f}_{l}^{p , q} ( {m}^{+} ) {s}_{{D}_{{m}^{+}}}^{p} ( t - {lT}_{s} - {T}^{p , q} ( {m}^{+} ) ) . \qquad ( 2 )$$

The multipath spread is assumed to be T^{p,q}(m)+N_{f}Tₛ<T_{g}, ∀p, q, m. A set of complex channels {fₗ^{p,q}(m)} includes an actual channel response and a bandwidth-efficient transmission pulse shape. Also, {fₗ^{p,q}(m)} is assumed to be constant over one packet duration but varies from packet to packet [8]. The additive noise n^{q}(t) is circular white Gaussian with spectral density 2N₀. The receiver is assumed to be matched to the transmitted pulse. Eliminating the guard interval for OFDM data symbols, received signal vectors are expressed as [5]

$$\begin{matrix}{r}^{q} ( 0 ) = {\sum }_{p = 1}^{{N}_{t}} S ( 0 ) {\tilde{D}}^{p} ( 0 ) {A}^{p , q} ( 0 ) C ( 0 ) {f}^{p , q} ( 0 ) + {n}^{q} ( 0 ) , & ( 3 ) \\ {r}^{q} ( {m}^{+} ) = {\sum }_{p = 1}^{{N}_{t}} S ( {m}^{+} ) {D}^{p} ( {m}^{+} ) {A}^{p , q} ( {m}^{+} ) C ( {m}^{+} ) {f}^{p , q} ( {m}^{+} ) + {n}^{q} ( {m}^{+} ) , & \\ where & \\ {r}^{q} ( 0 ) {=}^{Δ} [ \begin{matrix}{r}_{0}^{q} ( {nT}_{N , d}^{t , g} ) \\ {r}_{0}^{q} ( {T}_{s} + {nT}_{N , d}^{t , g} ) \\ ⋮ \\ {r}_{0}^{q} ( ( {M}_{t} - 1 ) {T}_{s} + {nT}_{N , d}^{t , g} )\end{matrix} ] ∈ {𝒞}^{{M}_{t}} , & ( 4 ) \\ {r}^{q} ( {m}^{+} ) {=}^{Δ} [ \begin{matrix}{r}_{{m}^{+}}^{q} ( {T}_{t} + {T}_{g} + {T}_{d}^{g} ( {m}^{+} - 1 ) + {nT}_{N , d}^{t , g} ) ` \\ {r}_{{m}^{+}}^{q} ( {T}_{s} + {T}_{t} + {T}_{g} + {T}_{d}^{g} ( {m}^{+} - 1 ) + {nT}_{N , d}^{t , g} ) \\ ⋮ \\ {r}_{{m}^{+}}^{q} ( \begin{matrix}( K - 1 ) {T}_{s} + {T}_{t} + {T}_{g} + \\ {T}_{d}^{g} ( {m}^{+} - 1 ) + {nT}_{N , d}^{t , g}\end{matrix} )\end{matrix} ] ∈ {𝒞}^{K} , & \\ {n}^{q} ( 0 ) \sim 𝒩 ( {n}^{q} ( 0 ) ; 0 , 2 {N}_{0} / {T}_{s} {I}_{{M}_{t} \times {M}_{t}} ) , & \\ {n}^{q} ( {m}^{+} ) \sim 𝒩 ( {n}^{q} ( {m}^{+} ) ; 0 , 2 {N}_{0} / {T}_{s} {I}_{K \times K} ) , & \\ S ( 0 ) {=}^{Δ} [ {s}_{0} ( 0 ) , {s}_{1} ( 0 ) , … , {s}_{{M}_{t - 1}} ( 0 ) ] ∈ {𝒞}^{{M}_{t} \times {M}_{t}} , & \\ S ( {m}^{+} ) {=}^{Δ} [ {s}_{0} ( {m}^{+} ) , {s}_{1} ( {m}^{+} ) , … , {s}_{K - 1} ( {m}^{+} ) ] ∈ {𝒞}^{K \times K} , & \\ {s}_{k} ( 0 ) = 1 / {\sqrt{{M}_{t}} [ 1 , {ⅇ}^{j2 π {kT}_{s} / {T}_{t}} , … , {ⅇ}^{j2 π k ( {M}_{t} - 1 ) {T}_{s} / {T}_{t}} ]}^{T} ∈ {𝒞}^{{M}_{t}} , & \\ {s}_{k} ( {m}^{+} ) = 1 / {\sqrt{K} [ 1 , {ⅇ}^{j2 π {kT}_{s} / {T}_{d}} , … , {ⅇ}^{j2 π k ( K - 1 ) {T}_{s} / {T}_{d}} ]}^{T} ∈ {𝒞}^{K} , & \\ {\tilde{D}}^{p} ( 0 ) {=}^{Δ} diag \{ {\tilde{d}}_{0}^{p} ( 0 ) , {\tilde{d}}_{1}^{p} ( 0 ) , … , {\tilde{d}}_{{M}_{t} - 1}^{p} ( 0 ) \} , & \\ {D}^{p} ( {m}^{+} ) {=}^{Δ} diag \{ {d}_{0}^{p} ( {m}^{+} ) , {d}_{1}^{p} ( {m}^{+} ) , … , {d}_{K - 1}^{p} ( {m}^{+} ) \} , & \\ {A}^{p , q} ( 0 ) {=}^{Δ} & \\ diag \{ 1 , {ⅇ}^{- j2 π {T}^{p , q} ( 0 ) / {T}_{t}} , … , {ⅇ}^{- j2 π ( {M}_{t} - 1 ) {T}^{p , q} ( 0 ) / {T}_{t}} \} ∈ {𝒞}^{{M}_{t} \times {M}_{t}} , & \\ {A}^{p , q} ( {m}^{+} ) {=}^{Δ} & \\ diag \{ 1 , {ⅇ}^{- j2 π {T}^{p , q} ( {m}^{+} ) / {T}_{d}} , … , {ⅇ}^{- j2 π ( K - 1 ) {T}^{p , q} ( {m}^{+} ) / {T}_{d}} \} ∈ {𝒞}^{K \times K} , & \\ C ( 0 ) {=}^{Δ} [ {c}_{0}^{T} ( 0 ) , {c}_{1}^{T} ( 0 ) , … , {c}_{{M}_{t - 1}}^{T} ( 0 ) ] ∈ {𝒞}^{{M}_{t} \times {N}_{f}} , & \\ C ( {m}^{+} ) {=}^{Δ} [ {c}_{0}^{T} ( {m}^{+} ) , {c}_{1}^{T} ( {m}^{+} ) , … , {c}_{K - 1}^{T} ( {m}^{+} ) ] ∈ {𝒞}^{K \times {N}_{f}} , & \\ {c}_{k}^{T} ( 0 ) {=}^{Δ} {[ 1 , {ⅇ}^{- j 2 π {kT}_{s} / {T}_{t}} , … , {ⅇ}^{- j 2 π k ( {N}_{f} - 1 ) {T}_{s} / {T}_{t}} ]}^{T} ∈ {𝒞}^{{N}_{f}} , & \\ {c}_{k}^{T} ( {m}^{+} ) {=}^{Δ} {[ 1 , {ⅇ}^{- j 2 π {kT}_{s} / {T}_{d}} , … , {ⅇ}^{- j 2 π k ( {N}_{f} - 1 ) {T}_{s} / {T}_{d}} ]}^{T} ∈ {𝒞}^{{N}_{f}} , & \\ {f}^{p , q} ( m ) {=}^{Δ} {[ {f}_{0}^{p , q} ( m ) , {f}_{1}^{p , q} ( m ) , … , {f}_{{N}_{f} - 1}^{p , q} ( m ) ]}^{T} ∈ {𝒞}^{{N}_{f}} . & \end{matrix}$$

Note that r^{q}(0) and r^{q}(m⁺) are sufficient statistics. Also, S(0) and S( [symbol] ) are IFFT matrices satisfying S(0)S(0)^{H}=S(0)^{H}S(0)=I_{M}_{ₜ}_{×M}_{ₜ} and S(m⁺)S(m⁺)^{H}=S(m⁺)^{H}S(m⁺)=I_{K×K}. The detailed derivation of (3) is given in [5]. Examining all definitions in (4), we observe that they are involved in either Mₜ subcarriers or K subcarriers, so that we may focus only on the m-th OFDM symbol without confusion.

The demodulator output (a K-point FFT) are now given by

$$\begin{matrix}{y}^{q} ( m ) {=}^{Δ} {S ( m )}^{H} {r}^{q} ( m ) \\ = {\sum }_{p = 1}^{{N}_{t}} {D}^{p} ( m ) {A}^{p , q} ( m ) C ( m ) {f}^{p , q} ( m ) + {z}^{q} ( m ) , \\ {y}_{k}^{q} ( m ) {=}^{Δ} {( {y}^{q} ( m ) )}_{k} \\ = {\sum }_{p = 1}^{{N}_{t}} {ⅇ}^{- j 2 π k {T}^{p , q} ( m ) / {T}_{d}} {c}_{k} ( m ) {f}^{p , q} ( m ) {d}_{k}^{p} ( m ) + {z}_{k}^{q} ( m ) , \\ {=}^{Δ} {\sum }_{p = 1}^{{N}_{t}} {ⅇ}^{- j 2 π k {T}^{p , q} ( m ) / {T}_{d}} {F}^{p , q} ( m ) {d}_{k}^{p} ( m ) + {z}_{k}^{q} ( m ) ,\end{matrix} \qquad ( 5 )$$

where z^{q}(m)˜N(z^{q}(m); 0, 2N₀/TₛI_{K×K}), zₖ^{q}(m)˜N(zₖ^{q}(m); 0, 2N₀/Tₛ). This can be used to find an effective strategy to detect {d^{p}(m)} and jointly estimate a set of channel parameters {{fₗ^{p,q}(m)}, {T^{p,q}(m)}} from the received samples. To simplify our approach, we assume that {T^{p,q}(m)} is exactly known a priori. At the receiver, the channel is estimated by using the EM-based method and its estimate is used by the soft-QRD-M data detector, which will be discussed in the next two sections. Then, the detected data is multiplexed and decoded. An exemplifying algorithm for a data detection will be described in the following section. Notice that the detected data based on the previous channel estimate is involved in this section.

Using the received signal at the k-th subcarrier, defined in (5), the received signal vector over the k-th subcarrier is

$${y}_{k} ( m ) {=}^{Δ} {[ {y}_{k}^{1} ( m ) , {y}_{k}^{2} ( m ) , … , {y}_{k}^{{N}_{r}} ( m ) ]}^{T} , \\ {=}^{Δ} {F}_{k} ( m ) {d}_{k} ( m ) + {z}_{k} ( m ) , \\ {F}_{k} ( m ) {=}^{Δ} [ \begin{matrix}{α}_{k}^{1 , 1} ( m ) {F}_{k}^{1 , 1} ( m ) & {α}_{k}^{1 , 2} ( m ) {F}_{k}^{1 , 2} ( m ) & … & {α}_{k}^{1 , {N}_{t}} ( m ) {F}_{k}^{1 , {N}_{t}} ( m ) \\ {α}_{k}^{2 , 1} ( m ) {F}_{k}^{2 , 1} ( m ) & {α}_{k}^{2 , 2} ( m ) {F}_{k}^{2 , 2} ( m ) & … & {α}_{k}^{2 , {N}_{t}} ( m ) {F}_{k}^{2 , {N}_{t}} ( m ) \\ ⋮ & ⋮ & … & ⋮ \\ {α}_{k}^{{N}_{r} , 1} ( m ) {F}_{k}^{{N}_{r} , 1} ( m ) & {α}_{k}^{{N}_{r} , 2} ( m ) {F}_{k}^{{N}_{r} , 2} ( m ) & … & {α}_{k}^{{N}_{r} , {N}_{t}} ( m ) {F}_{k}^{{N}_{r} , {N}_{t}} ( m )\end{matrix} ] \\ {=}^{Δ} [ {f}_{1} ( m ) , {f}_{2} ( m ) , … , {f}_{{N}_{t}} ( m ) ] ∈ {𝒞}^{{N}_{r} \times {N}_{t}} , \\ {α}_{k}^{p , q} ( m ) {=}^{Δ} {ⅇ}^{- j 2 π {kT}^{p , q} ( m ) / {T}_{d}} , \\ {d}_{k} ( m ) {=}^{Δ} {[ {d}_{k}^{1} ( m ) , {d}_{k}^{2} ( m ) , … , {d}_{k}^{{N}_{t}} ( m ) ]}^{T} , \\ {z}_{k} ( m ) \sim 𝒩 ( {z}_{k} ( m ) ; 0 , 2 {N}_{0} / {T}_{s} {I}_{{N}_{r} \times {N}_{r}} ) . \qquad ( 6 )$$

For this received signal vector, we first apply the QR decomposition (QRD) to an estimated channel matrix \hat{F}ₖ(m), that is,
\hat{F}ₖ(m)=\hat{Q}ₖ(m)\hat{R}ₖ(m), (7)
where \hat{Q}ₖ(m) is unitary matrix satisfying \hat{Q}ₖ^{H}(m)\hat{Q}ₖ(m)=\hat{Q}ₖ(m)\hat{Q}ₖ^{H}(m)=I_{N}_{ₜ}_{×N}_{ₜ}. Also, \hat{R}ₖ(m) is upper triangular matrix. Multiplying the received signal vector by \hat{Q}ₖ^{H}(m), we get the following equations
yₖ(m)=\hat{F}ₖ(m)dₖ(m)+zₖ(m),
\hat{Q}ₖ^{H}(m)yₖ(m)=\hat{R}ₖ(m)dₖ(m)+\hat{Q}ₖ^{H}(m)zₖ(m),
\tilde{y}ₖ^{U}(m)Δ\hat{R}ₖ(m)dₖ(m)+\tilde{z}ₖ^{U}(m). (8)
Note that \tilde{y}ₖ^{U}(m) is sufficient statistics and \tilde{z}ₖ^{U}(m)˜N(\tilde{z}ₖ^{U}(m), 0, 2N₀/TₛI). Also, multiplying the unitary matrix \hat{Q}ₖ^{H}(m) does not change the whiteness of the noise process, zₖ(m).

To reduce the error propagation with the data detection, we rearrange the data vector using the estimated data power as dₖ(m)=[dₖ⁽¹⁾(m), . . . , dₖ^{(N}^{ₜ}⁾(m)]^{T}, such that [5]
∥\hat{f}₍₁₎(m)∥²≦∥\hat{f}₍₂₎(m)∥²≦ . . . ≦∥\hat{f}_{(N}_{ₜ}₎(m)∥². (9)

Throughout this example (j) denotes the i-th strongest data. The complex-valued dₖ⁽ⁱ⁾(m) is identically represented as a binary Q-tuple, that is,
dₖ⁽ⁱ⁾(m)ΔM(bₖⁱ),b_{k,j}ⁱε{0,1},dₖ⁽ⁱ⁾(m)εC,
bₖⁱΔ{b_{k,1}ⁱ,b_{k,2}ⁱ, . . . , b_{k,Q}ⁱ}ε{0,1}^{Q}, (10)
where M(.) is a mapping function. To simplify notations for a binary bit representation, the dependence on the OFDM data symbol index m will be suppressed in the sequel. Without specifying we assume that the data detection ordering is determined by (9). Denoting by
b_{k,j}ⁱ⁺Δ{b_{k,1}ⁱ,b_{k,2}ⁱ, . . . , b_{k,j}ⁱ=1, . . . , b_{k,Q}ⁱ}ε{0,1}^{Q-1},
b_{k,j}ⁱ⁻Δ{b_{k,1}ⁱ,b_{k,2}ⁱ, . . . , b_{k,j}ⁱ=0, . . . , b_{k,Q}ⁱ}ε{0,1}^{Q-1}, (11)
we have the soft-QRD-M detector generates the soft information from all available observations
p(b_{k,j}ⁱ=0|(\tilde{y}ₖ^{U}(m))_{N}_{ₜ}, . . . , (\tilde{y}ₖ^{U}(m))₁) and p(b_{k,j}ⁱ=1|(\tilde{y}ₖ^{U}(m))_{N}_{ₜ}, . . . , (\tilde{y}ₖ^{U}(m))₁), (12)
which can be written as

$$p ( {b}_{k , j}^{i} = 1 \vert {( {\tilde{y}}_{k}^{U} ( m ) )}_{{N}_{t}} , … , {( {\tilde{y}}_{k}^{U} ( m ) )}_{1} ) = {\sum }_{{b}_{k}^{1} ∈ {\{ 0 , 1 \}}^{Q}} , … , {\sum }_{{b}_{k , j}^{1 , +} ∈ {\{ 0 , 1 \}}^{Q - 1}} , … , {\sum }_{{b}_{k}^{{N}_{t}} ∈ {\{ 0 , 1 \}}^{Q}} p ( {b}_{k}^{1} , … , {b}_{k , j}^{i , +} , … , {b}_{k}^{{N}_{t}} \vert {( {\tilde{y}}_{k}^{U} ( m ) )}_{{N}_{t}} , … , {( {\tilde{y}}_{k}^{U} ( m ) )}_{1} ) , \\ p ( {b}_{k , j}^{i} = 0 \vert {( {\tilde{y}}_{k}^{U} ( m ) )}_{{N}_{t}} , … , {( {\tilde{y}}_{k}^{U} ( m ) )}_{1} ) = {\sum }_{{b}_{k}^{1} ∈ {\{ 0 , 1 \}}^{Q}} , … , {\sum }_{{b}_{k , j}^{1 , -} ∈ {\{ 0 , 1 \}}^{Q - 1}} , … , {\sum }_{{b}_{k}^{{N}_{t}} ∈ {\{ 0 , 1 \}}^{Q}} p ( {b}_{k}^{1} , … , {b}_{k , j}^{i , -} , … , {b}_{k}^{{N}_{t}} \vert {( {\tilde{y}}_{k}^{U} ( m ) )}_{{N}_{t}} , … , {( {\tilde{y}}_{k}^{U} ( m ) )}_{1} ) . \qquad ( 13 )$$

Note that this is the marginal conditional probability (MCP), or the global function called in the Factor Graph theory [9]. Using both the Bayesian approach and the property of the QRD, the conditional probability in (13) can be computed as

$$p ( {b}_{k}^{1} , … , {b}_{k , j}^{i , +} , … , {b}_{k}^{{N}_{t}} \vert {( {\tilde{y}}_{k}^{U} ( m ) )}_{{N}_{t}} , … , {( {\tilde{y}}_{k}^{U} ( m ) )}_{1} ) = {c}_{1} \times p ( {( {\tilde{y}}_{k}^{U} ( m ) )}_{1} \vert {b}_{k}^{1} , … , {b}_{k , j}^{i , +} , … , {b}_{k}^{{N}_{t}} ) p ( {b}_{k}^{1} ) \times p ( {( {\tilde{y}}_{k}^{U} ( m ) )}_{2} \vert {b}_{k}^{2} , … , {b}_{k , j}^{i , +} , … , {b}_{k}^{{N}_{t}} ) p ( {b}_{k}^{2} ) \times … \times p ( {( {\tilde{y}}_{k}^{U} ( m ) )}_{i - 1} \vert {b}_{k}^{i - 1} , … , {b}_{k , j}^{i , +} , … , {b}_{k}^{{N}_{t}} ) p ( {b}_{k}^{i - 1} ) \times p ( {( {\tilde{y}}_{k}^{U} ( m ) )}_{i} \vert {b}_{k , j}^{i , +} , … , {b}_{k}^{{N}_{t}} ) p ( {b}_{k , j}^{i , +} ) \times p ( {( {\tilde{y}}_{k}^{U} ( m ) )}_{i + 1} \vert {b}_{k}^{i , + 1} , … , {b}_{k}^{{N}_{t}} ) p ( {b}_{k}^{i + 1} ) \times … \times p ( {( {\tilde{y}}_{k}^{U} ( m ) )}_{{N}_{t}} \vert {b}_{k}^{{N}_{t}} ) p ( {b}_{k}^{{N}_{t}} ) , \qquad ( 14 )$$

where c₁ is a constant. With a sufficient interleaver, a set of a priori distributions is computed using a set of input log-likelihood ratios (LLRs), {L(b_{k,j}ⁱ), i=1, . . . , Nₜ, j=1, . . . , Q},

$$p ( {b}_{k}^{l} ) = {\prod }_{j = 1}^{Q} \frac{{ⅇ}^{\{ {b}_{k , j}^{l} \times L ( {b}_{k , j}^{l} ) \}}}{1 + {ⅇ}^{L ( {b}_{k , j}^{l} )}} , l = 1 , 2 , … , i - 1 , i + 1 , … , {N}_{t} , \\ p ( {b}_{k , j}^{i , +} ) = {\prod }_{l = 1}^{j - 1} \frac{{ⅇ}^{\{ {b}_{k , l}^{i} \times L ( {b}_{k , l}^{i} ) \}}}{1 + {ⅇ}^{L ( {b}_{k , l}^{i} )}} \frac{{ⅇ}^{L ( {b}_{k , j}^{i} )}}{1 + {ⅇ}^{L ( {b}_{k , j}^{i} )}} {\prod }_{l = j + 1}^{Q} \frac{{ⅇ}^{\{ {b}_{k , l}^{i} \times L ( {b}_{k , l}^{i} ) \}}}{1 + {ⅇ}^{L ( {b}_{k , l}^{i} )}} , \\ p ( {b}_{k , j}^{i , -} ) = {\prod }_{l = 1}^{j - 1} \frac{{ⅇ}^{\{ {b}_{k , l}^{i} \times L ( {b}_{k , l}^{i} ) \}}}{1 + {ⅇ}^{L ( {b}_{k , l}^{i} )}} \frac{1}{1 + {ⅇ}^{L ( {b}_{k , j}^{i} )}} {\prod }_{l = j + 1}^{Q} \frac{{ⅇ}^{\{ {b}_{k , l}^{i} \times L ( {b}_{k , l}^{i} ) \}}}{1 + {ⅇ}^{L ( {b}_{k , l}^{i} )}} . \qquad ( 15 )$$

A set of likelihoods in (14) is easily computed from the property of the QRD, such that

$$\begin{matrix}p ( {( {\tilde{y}}_{k}^{U} ( m ) )}_{l} \vert {b}_{k}^{l} , … , {b}_{k , j}^{i , +} , … , {b}_{k}^{{N}_{t}} ) = \frac{1}{π 2 ( {N}_{0} / {T}_{s} )} {ⅇ}^{- \frac{( . )}{2 ( {N}_{0} / {T}_{s} )}} , \\ where & ( 16 ) \\ {ⅇ}^{- \frac{( . )}{2 ( {N}_{0} / {T}_{s} )} {=}^{Δ} {ⅇ}^{- ( \frac{{‖ {( {\tilde{y}}_{k}^{U} ( m ) )}_{l} - {\sum }_{m = l , m \neq i}^{{N}_{t}} {\{ {\hat{R}}_{k} ( m ) )}_{l , m} M ( {b}_{k}^{m} ) - {( {\hat{R}}_{k} ( m ) )}_{l , i} M ( {b}_{k , j}^{i , +} ) ‖}^{2}}{2 ( {N}_{0} / {T}_{s} )} )} .} & ( 17 )\end{matrix}$$

Here a set of {M(bₖ^{m}), m=1, . . . , j−1, j, . . . , Nₜ} and M(b_{k,j}^{i,+}) are signal mappings. Using the definitions in (14), (15), and (16), we can compute (13). However, we need to consider 2^{(N-1)×N}^{ₜ} hypotheses. In a higher subcarrier modulation and a GO OFDM system, this results in a prohibitive complexity. To reduce it and be less sensitive to the detection error propagation, we modify the M-algorithm proposed in [4],[5].

For defining a soft QRD-M algorithm we assume that the data detection ordering is determined already. For Nₜ=Nᵣ=3, and the QPSK subcarrier modulation, the soft information p(b_{k,2}²=1|(\tilde{y}ₖ^{U}(m))₃, . . . , (\tilde{y}ₖ^{U}(m))₁) is computed as

$$p ( {b}_{k , 2}^{2} = 1 \vert {( {\tilde{y}}_{k}^{U} ( m ) )}_{3} , … , {( {\tilde{y}}_{k}^{U} ( m ) )}_{1} ) = {\sum }_{{b}_{k}^{1}} {\sum }_{{b}_{k , 2}^{2 , +}} {\sum }_{{b}_{k}^{3}} p ( {b}_{1}^{1} , {b}_{k , 2}^{2 , +} , {b}_{k}^{3} \vert {( {\tilde{y}}_{k}^{U} ( m ) )}_{3} , … , {( {\tilde{y}}_{k}^{U} ( m ) )}_{1} ) , ∝ {\sum }_{{b}_{k}^{1}} {\sum }_{{b}_{k , 2}^{2 , +}} {\sum }_{{b}_{k}^{3}} p ( a ) \times p ( b ) \times p ( c ) , = \{ {\sum }_{{b}_{k}^{1}} [ {\sum }_{{b}_{k , 2}^{2 , +}} ( {\sum }_{{b}_{k}^{3}} p ( a ) ) p ( b ) ] p ( c ) \} , p ( a ) {=}^{Δ} p ( {( {\tilde{y}}_{k}^{U} ( m ) )}_{3} \vert {b}_{k}^{3} ) p ( {b}_{k}^{3} ) , p ( b ) {=}^{Δ} p ( {( {\tilde{y}}_{k}^{U} ( m ) )}_{2} \vert {b}_{k , 2}^{2 , +} , {b}_{k}^{3} ) p ( {b}_{k , 2}^{2 , +} ) , p ( c ) {=}^{Δ} p ( {( {\tilde{y}}_{k}^{U} ( m ) )}_{1} \vert {b}_{k}^{1} , {b}_{k , 2}^{2 , +} , {b}_{k}^{3} ) p ( {b}_{k}^{1} ) . \qquad ( 18 )$$

The MCP (18) can be computed from the innermost term to the outermost term sequentially. This structure is somewhat similar to the sum-product algorithm (SPA) [9],[10], where we split the MCP into several small number of tasks which can be done after another. It is worth while to note that the computation order is exactly opposite of that advocated in the Factor Graph approach, in which the summation over bₖ¹ is carried out first, which involves only the computation of Σ_{b}_{ₖ}_{¹}p((\tilde{y}ₖ^{U}(m))₁|bₖ¹, b_{k,2}^{2;+}, bₖ³)p(bₖ¹). Since

$$f ( {b}_{k , 2}^{2 , +} , {b}_{k}^{3} ) {=}^{Δ} {\sum }_{{b}_{k}^{1}} p ( {( {\tilde{y}}_{k}^{U} ( m ) )}_{1} \vert {b}_{k}^{1} , {b}_{k , 2}^{2 , +} , {b}_{k}^{3} ) p ( {b}_{k}^{1} )$$

is a function of (b_{k,2}^{2,+}, bₖ³), this locally computed probability will be passed to a parent node which multiples the leaf node sum by p(\tilde{y}ₖ^{U}(m))₂|b_{k,2}^{2,+},bₖ³)p(b_{k,2}^{2,+}) and sums over b_{k,2}^{2,+}, that is,

$$f ( {b}_{k}^{3} ) {=}^{Δ} {\sum }_{{b}_{k , 2}^{2 , +}} {p ( {\tilde{y}}_{k}^{U} ( m ) )}_{2} \vert {b}_{k , 2}^{2 , +} , {b}_{k}^{3} ) p ( {b}_{k , 2}^{2 , +} ) f ( {b}_{k , 2}^{2 , +} , {b}_{k}^{3} ) .$$

Again, since it is a function of bₖ³, we can compute the MOP summing over bₖ³, that is,

$$\begin{matrix}p ( {b}_{k , 2}^{2} = 1 \vert ( {\tilde{y}}_{k}^{U} ( m ) ) 3 , … , {( {\tilde{y}}_{k}^{U} ( m ) )}_{1} ) \\ = {\sum }_{{b}_{k}^{3}} p ( {( {\tilde{y}}_{k}^{U} ( m ) )}_{3} \vert {b}_{k}^{3} ) p ( {b}^{3} ) f ( {b}_{k}^{3} ) .\end{matrix}$$

The proposed scheme is computationally less intensive than the Factor Graph according to the following procedures.

We firstly compute four terms related with a different hypothesis for bₖ³ at the first stage

$${δ}_{[ 0 , 0 ]}^{3} {=}^{Δ} {c}_{1} {ⅇ}^{- \frac{{‖ {( {\tilde{y}}_{k}^{U} ( m ) )}_{3} - {( {\hat{R}}_{k} ( m ) )}_{3 , 3} M ( {b}_{k , 1}^{3} = 0 , {b}_{k , 2}^{3} = 0 ) ‖}^{2}}{2 ( {N}_{0} / {T}_{s} )}} \frac{1}{1 + {ⅇ}^{L ( {b}_{k , 1}^{3} )}} \frac{1}{1 + {ⅇ}^{L ( {b}_{k , 2}^{3} )}} , \\ {δ}_{[ 0 , 1 ]}^{3} {=}^{Δ} {c}_{1} {ⅇ}^{- \frac{{‖ {( {\tilde{y}}_{k}^{U} ( m ) )}_{3} - {( {\hat{R}}_{k} ( m ) )}_{3 , 3} M ( {b}_{k , 1}^{3} = 0 , {b}_{k , 2}^{3} = 1 ) ‖}^{2}}{2 ( {N}_{0} / {T}_{s} )}} \frac{1}{1 + {ⅇ}^{L ( {b}_{k , 1}^{3} )}} \frac{{ⅇ}^{L ( {b}_{k , 2}^{3} )}}{1 + {ⅇ}^{L ( {b}_{k , 2}^{3} )}} , \\ {δ}_{[ 1 , 0 ]}^{3} {=}^{Δ} {c}_{1} {ⅇ}^{- \frac{{‖ {( {\tilde{y}}_{k}^{U} ( m ) )}_{3} - {( {\hat{R}}_{k} ( m ) )}_{3 , 3} M ( {b}_{k , 1}^{3} = 1 , {b}_{k , 2}^{3} = 0 ) ‖}^{2}}{2 ( {N}_{0} / {T}_{s} )}} \frac{{ⅇ}^{L ( {b}_{k , 2}^{3} )}}{1 + {ⅇ}^{L ( {b}_{k , 1}^{3} )}} \frac{1}{1 + {ⅇ}^{L ( {b}_{k , 2}^{3} )}} , \\ {δ}_{[ 1 , 1 ]}^{3} {=}^{Δ} {c}_{1} {ⅇ}^{- \frac{{‖ {( {\tilde{y}}_{k}^{U} ( m ) )}_{3} - {( {\hat{R}}_{k} ( m ) )}_{3 , 3} M ( {b}_{k , 1}^{3} = 1 , {b}_{k , 2}^{3} = 1 ) ‖}^{2}}{2 ( {N}_{0} / {T}_{s} )}} \frac{{ⅇ}^{L ( {b}_{k , 2}^{3} )}}{1 + {ⅇ}^{L ( {b}_{k , 1}^{3} )}} \frac{{ⅇ}^{L ( {b}_{k , 2}^{3} )}}{1 + {ⅇ}^{L ( {b}_{k , 2}^{3} )}} . \qquad ( 19 )$$

Once we computed these four terms, we only keep M maximums (in the example we assume M=2) for the next stage, that is, \tilde{b}ₖ³Δ{(b_{k,1}³=0,b_{k,2}³=0), (b_{k,1}³=1,b_{k,2}²=1)} and \tilde{Δ}³={δ_{[0,0]}³,δ_{[1,1]}³} Since we make a decision from the strongest effective channel sequentially, it will be tolerate to the detection error propagation which is a intrinsic problem in interference cancellers.

In the second stage, we need to compute the following

$$\begin{matrix}{\sum }_{{b}_{k , 2}^{2 , +}} ( {\sum }_{{b}_{k}^{3}} p ( a ) ) p ( b ) \approx {\sum }_{{b}_{k}^{3} ∈ {\tilde{b}}_{k}^{3}} {\sum }_{{b}_{k , 2}^{2 , +}} p ( a ) \times p ( b ) \\ = {\sum }_{{b}_{k}^{3} ∈ {\tilde{b}}_{k}^{3}} {\sum }_{{b}_{k , 1}^{2}} p ( a ) \times p ( {( {\tilde{y}}_{k}^{U} ( m ) )}_{2} \vert {b}_{k , 1}^{2 } , {b}_{k , 2}^{2} \\ = 1 , {b}_{k}^{3} ) p ( {b}_{k , 1}^{2} ) p ( {b}_{k , 2}^{2} = 1 ( ) 20 )\end{matrix}$$

In (20), the expression

$${\sum }_{{b}_{k}^{3} ∈ {\tilde{b}}_{k}^{3}} {\sum }_{{b}_{k , 1}^{2}} p ( a ) \times p ( {( {\tilde{y}}_{k}^{U} ( m ) )}_{2} \vert {b}_{k , 1}^{2} , {b}_{k , 2}^{2} = 1 , {b}_{k}^{3} ) p ( {b}_{k , 1}^{2} ) p ( {b}_{k , 2}^{2} = 1 )$$

is consisting of

$${δ}_{[ 0 , 0 , 0 , 1 ]}^{2} {=}^{Δ} {c}_{2} \times {δ}_{[ 0 , 0 ]}^{3} \times p ( {( {\tilde{y}}_{k}^{U} ( m ) )}_{2} \vert {b}_{k , 1}^{2} = 0 , {b}_{k , 2}^{2} = 1 , {b}_{k , 1}^{3} = 0 , {b}_{k , 2}^{3} = 0 ) p ( {b}_{k , 1}^{2} = 0 ) p ( {b}_{k , 2}^{2} = 1 ) = {c}_{2} {δ}_{[ 0 , 0 ]}^{3} {ⅇ}^{- \frac{{‖ {( {\tilde{y}}_{k}^{U} ( m ) )}_{2} - {( {\hat{R}}_{k} ( m ) )}_{2 , 2} M ( {b}_{k , 1}^{2} = 0 , {b}_{k , 2}^{2} = 1 ) - {( {\hat{R}}_{k} ( m ) )}_{2 , 3} M ( {b}_{k , 1}^{3} = 0 , {b}_{k , 2}^{3} = 0 ) ‖}^{2}}{2 ( {N}_{0} / {T}_{s} )}} p ( {b}_{k , 1}^{2} = 0 ) p ( {b}_{k , 2}^{2} = 1 ) , \\ {δ}_{[ 0 , 0 , 1 , 1 ]}^{2} {=}^{Δ} {c}_{2} \times {δ}_{[ 0 , 0 ]}^{3} \times p ( {( {\tilde{y}}_{k}^{U} ( m ) )}_{2} \vert {b}_{k , 1}^{2} = 1 , {b}_{k , 2}^{2} = 1 , {b}_{k , 1}^{3} = 0 , {b}_{k , 2}^{3} = 0 ) p ( {b}_{k , 1}^{2} = 1 ) p ( {b}_{k , 2}^{2} = 1 ) = {c}_{2} {δ}_{[ 0 , 0 ]}^{3} {ⅇ}^{- \frac{{‖ {( {\tilde{y}}_{k}^{U} ( m ) )}_{2} - {( {\hat{R}}_{k} ( m ) )}_{2 , 2} M ( {b}_{k , 1}^{2} = 1 , {b}_{k , 2}^{2} = 1 ) - {( {\hat{R}}_{k} ( m ) )}_{2 , 3} M ( {b}_{k , 1}^{3} = 0 , {b}_{k , 2}^{3} = 0 ) ‖}^{2}}{2 ( {N}_{0} / {T}_{s} )}} p ( {b}_{k , 1}^{2} = 1 ) p ( {b}_{k , 2}^{2} = 1 ) , \\ {δ}_{[ 1 , 1 , 0 , 1 ]}^{2} {=}^{Δ} {c}_{2} \times {δ}_{[ 1 , 1 ]}^{3} \times p ( {( {\tilde{y}}_{k}^{U} ( m ) )}_{2} \vert {b}_{k , 1}^{2} = 0 , {b}_{k , 2}^{2} = 1 , {b}_{k , 1}^{3} = 1 , {b}_{k , 2}^{3} = 1 ) p ( {b}_{k , 1}^{2} = 0 ) p ( {b}_{k , 2}^{2} = 1 ) = {c}_{2} {δ}_{[ 1 , 1 ]}^{3} {ⅇ}^{- \frac{{‖ {( {\tilde{y}}_{k}^{U} ( m ) )}_{2} - {( {\hat{R}}_{k} ( m ) )}_{2 , 2} M ( {b}_{k , 1}^{2} = 0 , {b}_{k , 2}^{2} = 1 ) - {( {\hat{R}}_{k} ( m ) )}_{2 , 3} M ( {b}_{k , 1}^{3} = 1 , {b}_{k , 2}^{3} = 1 ) ‖}^{2}}{2 ( {N}_{0} / {T}_{s} )}} p ( {b}_{k , 1}^{2} = 0 ) p ( {b}_{k , 2}^{2} = 1 ) , \\ {δ}_{[ 1 , 1 , 1 , 1 ]}^{2} {=}^{Δ} {c}_{2} \times {δ}_{[ 1 , 1 ]}^{3} \times p ( {( {\tilde{y}}_{k}^{U} ( m ) )}_{2} \vert {b}_{k , 1}^{2} = 1 , {b}_{k , 2}^{2} = 1 , {b}_{k , 1}^{3} = 1 , {b}_{k , 2}^{3} = 1 ) p ( {b}_{k , 1}^{2} = 1 ) p ( {b}_{k , 2}^{2} = 1 ) = {c}_{2} {δ}_{[ 1 , 1 ]}^{3} {ⅇ}^{- \frac{{‖ {( {\tilde{y}}_{k}^{U} ( m ) )}_{2} - {( {\hat{R}}_{k} ( m ) )}_{2 , 2} M ( {b}_{k , 1}^{2} = 1 , {b}_{k , 2}^{2} = 1 ) - {( {\hat{R}}_{k} ( m ) )}_{2 , 3} M ( {b}_{k , 1}^{3} = 1 , {b}_{k , 2}^{3} = 1 ) ‖}^{2}}{2 ( {N}_{0} / {T}_{s} )}} p ( {b}_{k , 1}^{2} = 1 ) p ( {b}_{k , 2}^{2} = 1 ) . \qquad ( 21 )$$

Having obtained four terms at the second stage {δ_{[0,0,0,1]}², δ_{[0,0,1,1]}², δ_{[1,1,0,1]}², δ_{[1,1,1,1]}²}, we need to keep only two maximums, \tilde{Δ}²={δ_{[0011]}², δ_{[1101]}²}, and b_{k,2}^{\tilde{2},+}Δ{(b_{k,1}²=1, b_{k,2}²=1), (b_{k,1}²=1, b_{k,2}³=1)}. Similarly, we can apply the same approach in the final stage. At the final stage, we need to compute using \tilde{Δ}³ and \tilde{Δ}² as

$${\sum }_{{b}_{k}^{1}} [ {\sum }_{{b}_{k , 2}^{2 , +}} ( {\sum }_{{b}_{k}^{3}} p ( a ) ) p ( b ) ] p ( c ) \approx {\sum }_{{b}_{k}^{1}} [ {\sum }_{{b}_{k , 2}^{2 , +} ∈ {\tilde{b}}_{k , 2}^{2 , +}} ( {\sum }_{{b}_{k}^{3} ∈ {\tilde{b}}_{k}^{3}} p ( a ) ) p ( b ) ] p ( c ) , \qquad ( 22 )$$

where \tilde{b}_{k,2}^{2,+} is a set for b_{k,2}^{2,+} maintained from the previous stage. With the similar approach to other bits, we can compute a set of soft informations and its log-likelihood ratios (LLRs)

$$L ( {b}_{k , j}^{i} \vert {( {\tilde{y}}_{k}^{U} ( m ) )}_{{N}_{t}} , … , {( {\tilde{y}}_{k}^{U} ( m ) )}_{1} ) ) {=}^{Δ} ln \frac{p ( {b}_{k , j}^{i} = 1 \vert {( {\tilde{y}}_{k}^{U} ( m ) )}_{{N}_{t}} , … , {( {\tilde{y}}_{k}^{U} ( m ) )}_{1} ) )}{p ( {b}_{k , j}^{i} = 0 \vert {( {\tilde{y}}_{k}^{U} ( m ) )}_{{N}_{t}} , … , {( {\tilde{y}}_{k}^{U} ( m ) )}_{1} ) )} , i = 1 , … , {N}_{t} , j = 1 , … , Q . \qquad ( 23 )$$

We can readily extend this approach to a general number of antennas and a subcarrier modulation. Now with determined LLRs, the decoder, mainly the Viterbi algorithm (VA), uses the expected value of the corresponding bit. This is computed as
b̅_{k,j}ⁱΔE[b_{k,j}ⁱ]=tan h(L(b_{k,j}ⁱ|(\tilde{y}ₖ^{U}(m))_{N}_{ₜ}, . . . , (\tilde{y}ₖ^{U}(m))₁))/2). (24)

The above describes examples how to define an encoder for low density parity check (LDPC). Definition of a coder/decoder pair may affect both the transmitter and receiver. The transmitter may have a set of parity check and LDPC code generator matrices, and the receiver may have a set of factor graphs defined for the channel/LDPC decoder. The factor graph specification may include required probabilistic specifications for transitions between channel nodes, codeword nodes and parity check nodes.

The embodiments enable use of a set of LDPC codes based on channel information stored in the transmitter and receiver, or available thereto. A correct LDPC code or codes may then be selected for use in decoding in adaptive manner.

A transmitter and receiver pair can adapt to different situations whilst use of correct LDPC codes is enabled. This enables the system to take into account features such as fading channel characteristics.

It is appreciated that although the embodiments of the invention relate to MIMO OFDM, it may be possible to construct a framework combining signal detection and LDPC codes for other MIMO systems. The present invention is therefore not restricted to be applied only in MIMO OFDM systems.

Although preferred embodiments of the apparatus and method embodying the present invention have been illustrated in the accompanying drawings and described in the foregoing detailed description, it will be understood that the invention is not limited to the embodiments disclosed, but is capable of numerous rearrangements, modifications and substitutions without departing from the spirit of the invention as set forth and defined by the following claims.

1. A method for generating a low density parity check code, the method comprising defining a framework combining symbol detection and low density parity check decoding, determining probabilistic information describing multiple-input-multiple-output channels, and generating a low density parity check code based on said framework and said probabilistic information describing multiple-input-multiple-output channels.

2. A method as defined in claim 1, further comprising: linking information relating to detected symbols using a factor graph; and checking nodes of the low density parity check code, wherein the framework comprises the factor graph.

3. A method as defined in claim 1, wherein said defining of the framework comprises: allowing successive interference cancellation for detected symbols using a matrix decomposition of a multiple-input-multiple-output channel matrix.

4. A method as defined in claim 3, wherein the matrix decomposition is a QR decomposition.

5. A method as defined in claim 3, wherein said defining of the framework comprises: allowing a further matrix decomposition of the multiple-input-multiple-output channel matrix.

6. A method as defined in claim 3, further comprising: performing the matrix decomposition for frequency bins of orthogonal frequency multiplexing.

7. A method as defined in claim 3, further comprising: generating the low density parity check code based on density evolution.

8. A method as defined in claim 1, further comprising: generating the low density parity check code based on exit charts.

9. A method for low density parity check decoding, the method comprising: receiving information transmitted, over multiple-input-multiple-output channels, determining said received information describing said multiple-input-multiple-output channels, and determining a low density parity check codeword relating to said received information and to a low density parity check code using at least said received information, said received information describing said multiple-input-multiple-output channels, and a framework combining a symbol detection and a low density parity check decoding.

10. A method as defined in claim 9, further comprising: designing said low density parity check code using said framework.

11. A method as defined in claim 9, further comprising: linking information relating to detected symbols using a factor graph; and checking nodes of said low density parity check code, wherein the framework comprises the factor graph.

12. A method as defined in claim 9, wherein said defining of the framework comprises: —allowing successive interference cancellation for detected symbols using a matrix decomposition of a multiple-input-multiple-output channel matrix.

13. A method as defined in claim 12, wherein the matrix decomposition is a QR decomposition.

14. A method as defined in claim 12, wherein the framework comprises: allowing a further matrix decomposition of the multiple-input-multiple-output channel matrix.

15. A method as defined in claim 12, further comprising: performing the matrix decomposition for frequency bins of orthogonal frequency multiplexing.

16. A method as defined in claim 9, comprising: selecting at least one encoder/decoder pair for a transmitter and receiver pair.

17. A computer program comprising program code means adapted to perform in claim 9 when the program is run on a computer.

18. A decoder for low density parity check codes, configured to receive information transmitted over multiple-input-multiple-output channels, determine information describing said multiple-input-multiple-output channels, and determine a low density parity check codeword relating to said received information and to a low density parity check code using at least said received information, said information describing said multiple-input-multiple-output channels, and a framework combining symbol detection and low density parity check decoding.

19. A decoder as defined in claim 17, wherein said low density parity check code is designed using said framework.

20. A decoder for low density parity check codes, comprising means for receiving information transmitted over multiple-input-multiple-output channels, means for determining said received information describing said multiple-input-multiple-output channels, and means for determining a low density parity check codeword relating to said received information and to a low density parity check code using at least said received information, said received information describing said multiple-input-multiple-output channels, and a framework combining a symbol detection and a low density parity check decoding.

21. A decoder as defined in claim 20, wherein said low density parity check code has been designed using said framework.

22. A communication system comprising a decoder as defined in claim 18.
